(19) United States
(12) Patent Application Publication
(10) Pub. No.: US 2025/0142773 A1
(43) Pub. Date: May 1, 2025

(54) COOLING SYSTEM ASSEMBLY

(71) Applicant: Cooler Master Co., Ltd., Taipei City (TW)

(72) Inventor: Tsung-Wei LIN, Taipei City (TW)

(21) Appl. No.: 18/924,029

(22) Filed: Oct. 23, 2024

(30) Foreign Application Priority Data
Oct. 25, 2023 (TW) 112211498

(51) Int. Cl. H05K 7/20

(52) U.S. Cl. CPC H05K 7/20272; H05K 7/20136; H05K 7/202; H05K 7/2039

(57) ABSTRACT

A cooling system assembly may include a housing and two pump assemblies. The housing includes two pump cavities, each, disposed parallel against each other, and an inlet and outlet. Each two pump cavities includes a pump cavity inlet and pump cavity outlet. Each two pump assemblies is disposed in each two pump cavities and includes an impeller casing and a liquid driving assembly. Each liquid driving assembly includes a power source and an impeller. Each impeller casing includes a driving chamber, driving chamber inlet, and driving chamber outlet. Each power source respectively drives each impeller to rotate relative to each driving chamber. Each impeller casing defines an inlet chamber separate from the driving chamber. Each driving chamber is fluidly connected to the inlet via each driving chamber inlet, each inlet chamber, and each pump cavity inlet. The outlet is fluidly connected to each driving chamber.

### RELATED APPLICATIONS

This US application claims the benefit of priority to Taiwan application no. 112211498, filed on Oct. 25, 2023, of which is incorporated herein by reference in its entirety.

### TECHNICAL FIELD

The present disclosure relates to heat-transfer components and assemblies, and more particularly, but not limited to, multi-pump unit assemblies.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling systems such as air-cooling systems and liquid cooling systems are used to efficiently dissipate the heat generated by the electronic device and, thereby ensure the standard operation of the electronic device.

In the case of liquid cooling systems for heat sources such as packaged integrated circuits, heat is dissipated from an upper surface of the packaged integrated circuit via upper surface adherence to a water block of a cooling system assembly. The cooling system assembly is commonly mounted to the packaged integrated circuit via attachment members such as screws and push pins. A heat exchange chamber of the water block is fluidly connected to a fluid circulating pump. The pump circulates cooling fluid inside of the heat exchange chamber in order to deliver the fluid at a lower temperature to the heat exchange chamber. As the fluid circulates in the heat exchange chamber, thermal energy is exchanged between water block and the fluid and, as a result, the temperature of the water block is reduced, and in turn, the temperature of the packaged integrated circuit is reduced, and the temperature of the fluid increases. Heat is transferred from the packaged integrated circuit to the water block, to the fluid, and then to the ambient environment. Notwithstanding however, increasing thermal conductivity of cooling systems continue to be challenging.

### SUMMARY OF THE INVENTION

The present disclosure provides a cooling system assembly with higher thermal conductivity.

In some aspects, the techniques described herein relate to a cooling system assembly, including a housing and two pump assemblies. The housing includes two pump cavities, an inlet, and an outlet. Each two pump cavities is disposed parallel against each other and fluidly connected to the inlet and to the outlet. Each two pump cavities includes a pump cavity inlet, and a pump cavity outlet. Each two pump assemblies is respectively disposed in each two pump cavities. Each two pump assemblies includes an impeller casing and a liquid driving assembly. The impeller casing includes a driving chamber, a driving chamber inlet, and a driving chamber outlet. The liquid driving assembly is disposed in the driving chamber. The liquid driving assembly includes a power source, and an impeller. Each impeller casing defines an inlet chamber separate from the driving chamber. Each power source is configured to respectively drive each impeller to rotate relative to each driving chamber. Each pump cavity inlet is respectively disposed between each inlet chamber and the inlet, and each pump cavity inlet respectively connects the inlet to each inlet chamber.

In some aspects, the techniques described herein relate to a cooling system assembly, further including a plurality of pillars respectively coupled between each two pump cavities and each two pump assemblies. The plurality of pillars is respectively disposed within each inlet chamber.

In some aspects, the techniques described herein relate to a cooling system assembly, wherein the power source includes a stator and a printed circuit board. In some aspects, the techniques described herein relate to a cooling system assembly, wherein each two pump assemblies further includes a fan disposed on each two pump assemblies.

In some aspects, the techniques described herein relate to a cooling system assembly, further including a base plate disposed on the housing and perpendicular to each two pump cavities. The base plate includes a plate cavity and a thermal contact surface on an opposite side of the plate cavity. The plate cavity includes a heat exchange chamber and a plurality of heat transfer surface features. The plurality of heat transfer surface features is disposed in the heat exchange chamber. The thermal contact surface is configured to be in thermal contact with a heat source. A heat exchange chamber outlet of the housing is disposed between the outlet and the heat exchange chamber, and the heat exchange chamber outlet connects the heat exchange chamber to the outlet.

In some aspects, the techniques described herein relate to a cooling system assembly, further including a flow plate and a fin flow plate. The fin flow plate is disposed on the plurality of heat transfer surface features and the flow plate is disposed on the fin flow plate and between the base plate and the housing. The flow plate includes two inlet slits. Each two inlet slits is longitudinally disposed through the flow plate and parallel towards each other. The fin flow plate includes two fin inlet slits. Each two fin inlet slits is longitudinally disposed through the fin flow plate and parallel towards each other. Each two fin inlet slits, each two inlet slits, each pump cavity outlet, and each driving chamber outlet are respectively disposed between the heat exchange chamber and each driving chamber, and each driving chamber outlet, each pump cavity outlet, each two inlet slits, and each two fin inlet slits respectively connect each driving chamber to the heat exchange chamber.

In some aspects, the techniques described herein relate to a cooling system assembly, wherein the flow plate further includes an outlet through hole. The outlet through hole is disposed between the outlet and the heat exchange chamber, and the outlet through hole further connects the heat exchange chamber to the outlet.

In some aspects, the techniques described herein relate to a cooling system assembly, wherein the flow plate further includes an outlet slit, and wherein the fin flow plate further includes a fin outlet slit. The outlet slit is longitudinally disposed centrally through the flow plate between each two inlet slits. The outlet slit includes a base end and a neck end. The fin outlet slit is longitudinally disposed centrally through the fin flow plate between each two fin inlet slits. The fin outlet slit includes a fin base end and a fin neck end. The outlet through hole is disposed connected to the neck end. The outlet slit and the fin outlet slit are respectively disposed between the outlet and the heat exchange chamber, and the fin outlet slit and outlet slit further connect the heat exchange chamber to the outlet.

In some aspects, the techniques described herein relate to a cooling system assembly, wherein a base width of the base end is equal to a fin base width of the fin base end and a neck width of the neck end is equal to a fin neck width of the fin neck end. The base width and the fin base width are greater than the neck width and the fin neck width.

In some aspects, the techniques described herein relate to a cooling system assembly, wherein the fin flow plate further includes a fin plate outlet cut-out disposed on an end of the fin neck end.

In some aspects, the techniques described herein relate to a cooling system assembly, further including at least one heat exchanger, and wherein the housing further includes a heat exchanger opening. Each inlet chamber is disposed between the inlet and the heat exchanger opening, and each inlet chamber respectively connects the inlet to the heat exchanger opening. The at least one heat exchanger is disposed in the heat exchanger opening.

In some aspects, the techniques described herein relate to a cooling system assembly, wherein the at least one heat exchanger further includes a heat exchanger fan disposed on the at least one heat exchanger.

In some aspects, the techniques described herein relate to a cooling system assembly, wherein the at least one heat exchanger includes a first heat exchanger including a first cover plate, a plurality of first heat transfer surface features, and a heat sink. The plurality of first heat transfer surface features is disposed on one side of the first cover plate and the heat sink is disposed on an opposite side of the first cover plate. The plurality of first heat transfer surface features is disposed in the heat exchanger opening.

In some aspects, the techniques described herein relate to a cooling system assembly, wherein the at least one heat exchanger includes a second heat exchanger including a second cover plate, a plurality of second heat transfer surface features, a thermoelectric module, and a second heat sink. The plurality of second heat transfer surface features is disposed on one side of the second cover plate and the thermoelectric module disposed on an opposite side of the second cover plate. The second heat sink is disposed on the thermoelectric module and the plurality of second heat transfer surface features is disposed in the heat exchanger opening.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of pump cavities and pump assemblies incorporating aspects of the presently disclosed principles are illustrated by way of example, and not by way of limitation.

FIG. 1A illustrates a perspective view of a cooling system assembly, in accordance with various embodiments of the present disclosure.

FIG. 1B illustrates another perspective view of the cooling system assembly of FIG. 1A, in accordance with various embodiments of the present disclosure.

FIG. 2 illustrates a cross-sectional view of the cooling system assembly of FIG. 1A, in accordance with various embodiments of the present disclosure.

FIG. 3 illustrates a partially exploded view of the cooling system assembly of FIG. 1A, in accordance with various embodiments of the present disclosure.

FIG. 4 illustrates another cross-sectional view of the cooling system assembly of FIG. 1A, in accordance with various embodiments of the present disclosure.

FIG. 5A illustrates another partially exploded view of the cooling system assembly of FIG. 1A, in accordance with various embodiments of the present disclosure.

FIG. 5B illustrates yet another partially exploded view of the cooling system assembly of FIG. 1A, in accordance with various embodiments of the present disclosure.

FIG. 6A illustrates a perspective view of an alternative cooling system assembly, in accordance with various embodiments of the present disclosure.

FIG. 6B illustrates a partially exploded view of the alternative cooling system assembly of FIG. 6A, in accordance with various embodiments of the present disclosure.

FIG. 6C illustrates another partially exploded view of the alternative cooling system assembly of FIG. 6A, in accordance with various embodiments of the present disclosure.

FIG. 7 illustrates a cross-sectional view of the cooling system assembly of FIG. 6A, in accordance with various embodiments of the present disclosure.

FIG. 8A illustrates a perspective view of another alternative cooling system assembly, in accordance with various embodiments of the present disclosure.

FIG. 8B illustrates a cross-sectional view of the another alternative cooling system assembly of FIG. 8A, in accordance with various embodiments of the present disclosure.

### DETAILED DESCRIPTION

The following describes various principles related to components and assemblies for electronic devices cooling by way of reference to specific examples of cooling system assemblies, including specific arrangements and examples of pump cavities and pump assemblies embodying innovative concepts. More particularly, but not exclusively, such innovative principles are described in relation to selected examples of liquid chambers and openings, and liquid inlets, outlets, slits, and cut-outs, and well-known functions or constructions are not described in detail for purposes of succinctness and clarity. Nonetheless, one or more of the disclosed principles can be incorporated in various other embodiments of liquid chambers and openings, and liquid inlets, outlets, slits, and cut-outs to achieve any of a variety of desired outcomes, characteristics, and/or performance criteria.

Thus, liquid chambers and openings, and liquid inlets, outlets, slits, and cut-outs having attributes that are different from those specific examples discussed herein can embody one or more of the innovative principles, and can be used in applications not described herein in detail. Accordingly, embodiments of liquid chambers and openings, and liquid inlets, outlets, slits, and cut-outs not described herein in detail also fall within the scope of this disclosure, as will be appreciated by those of ordinary skill in the relevant art following a review of this disclosure.

Example embodiments as disclosed herein are directed to liquid cooling systems, wherein a base plate is in thermal contact with electronic components, transporting heat away therefrom, and then cooling fluid, circulating inside of a cooling loop system incorporating the base plate, flows over the base plate by two pump assemblies, removing heat therefrom. The heated cooling fluid is output from the base plate and may be input to a heat dissipation device, such as a heat pipe radiator. The heated cooling fluid may flow to and through the heat pipe radiator, and then the cooling fluid may flow from the heat pipe radiator to the two pump assemblies and the base plate to once again begin the cooling loop.

The cooling system assemblies may be configured on a chassis, within a chassis, or as part of an electronics system that includes heat producing electronic components to be cooled. The cooling system assemblies include at least one liquid-based cooling loop, and may further comprise one or more fans. The one or more fans may be coupled to the cooling system assemblies via fasteners (e.g., bolts, screws, etc.) at structural portions of the cooling system assemblies, transporting air to the cooling system assemblies, or to an air plenum or to an outside of the chassis or electronics system. The cooling system assembly may be coupled to the chassis via fasteners (e.g., bolts, screws, etc.).

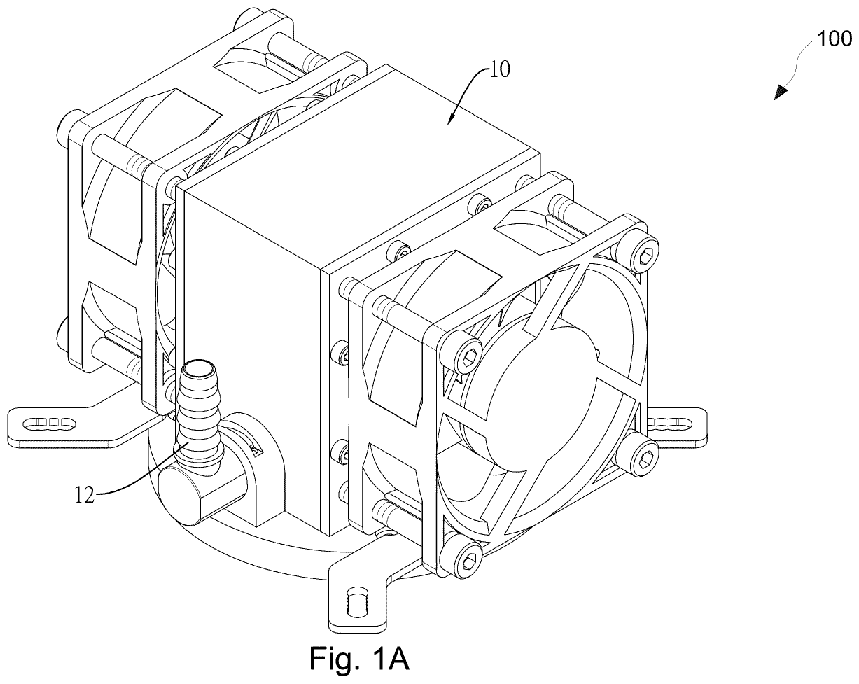

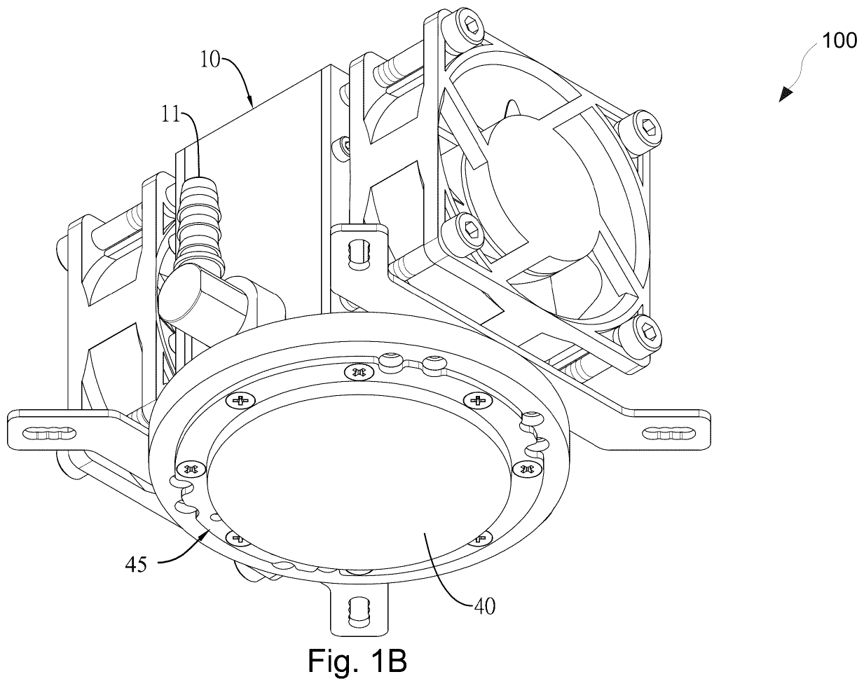

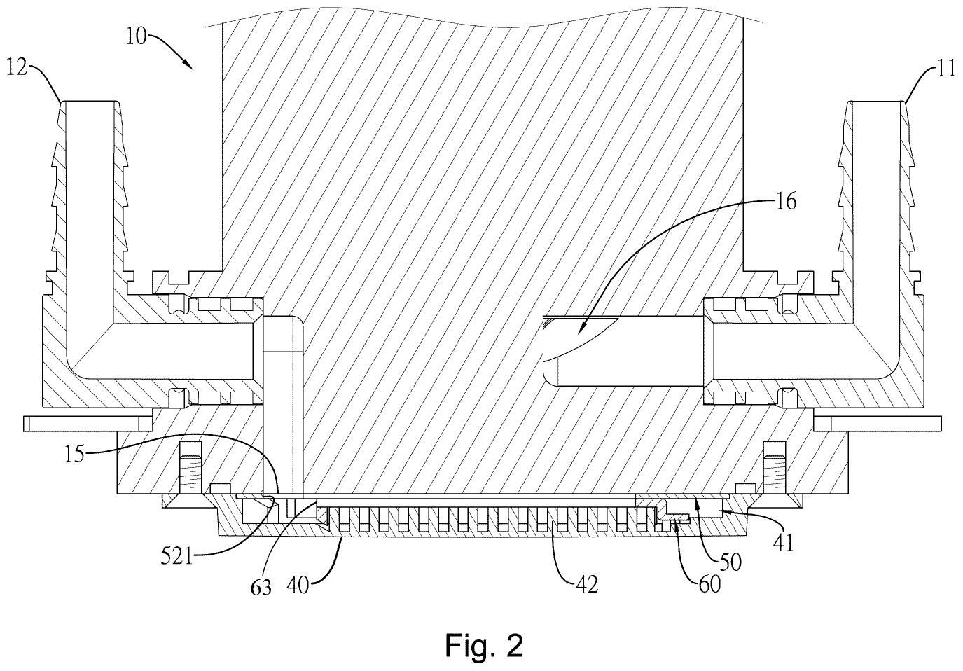

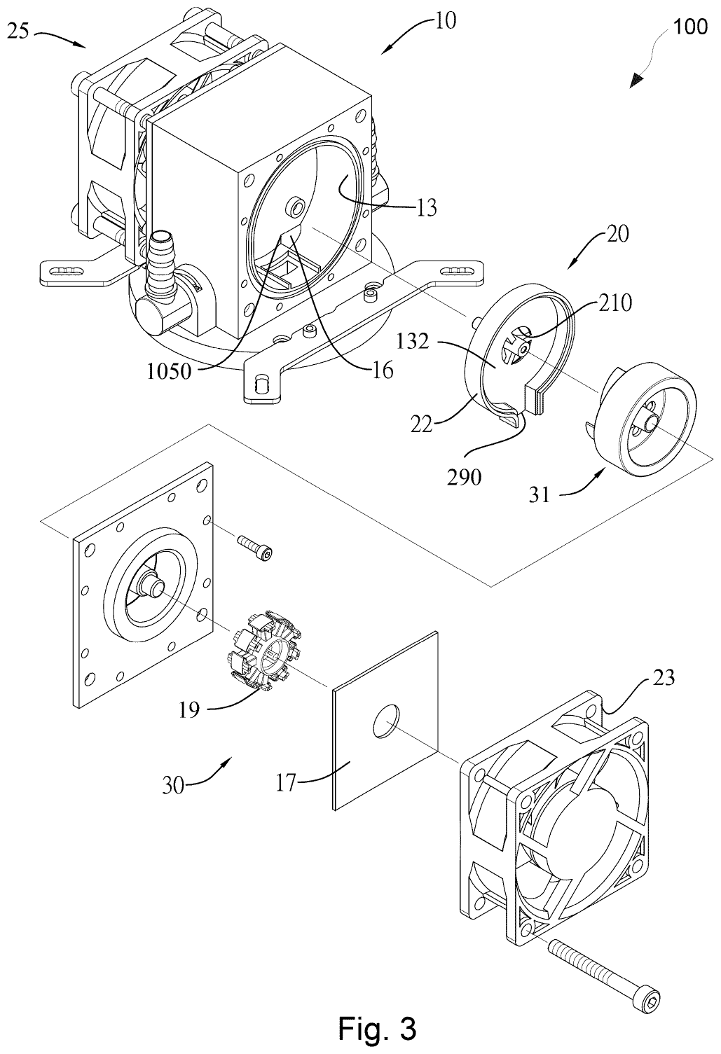

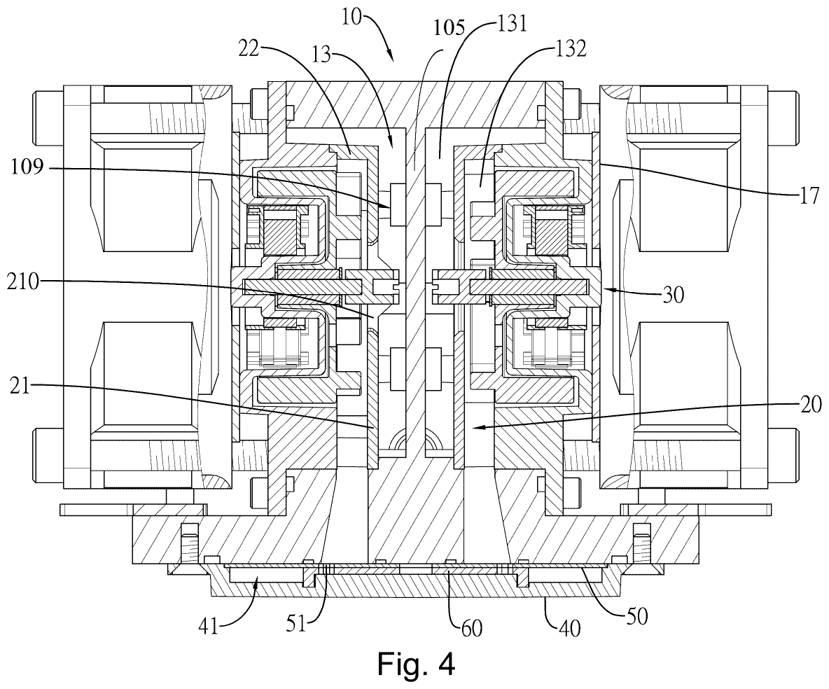

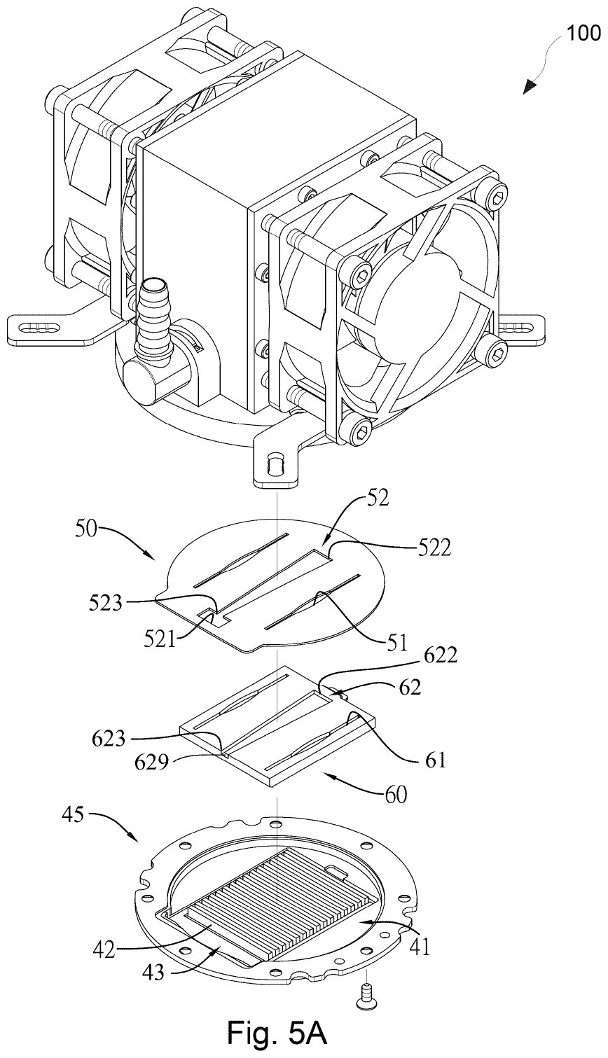

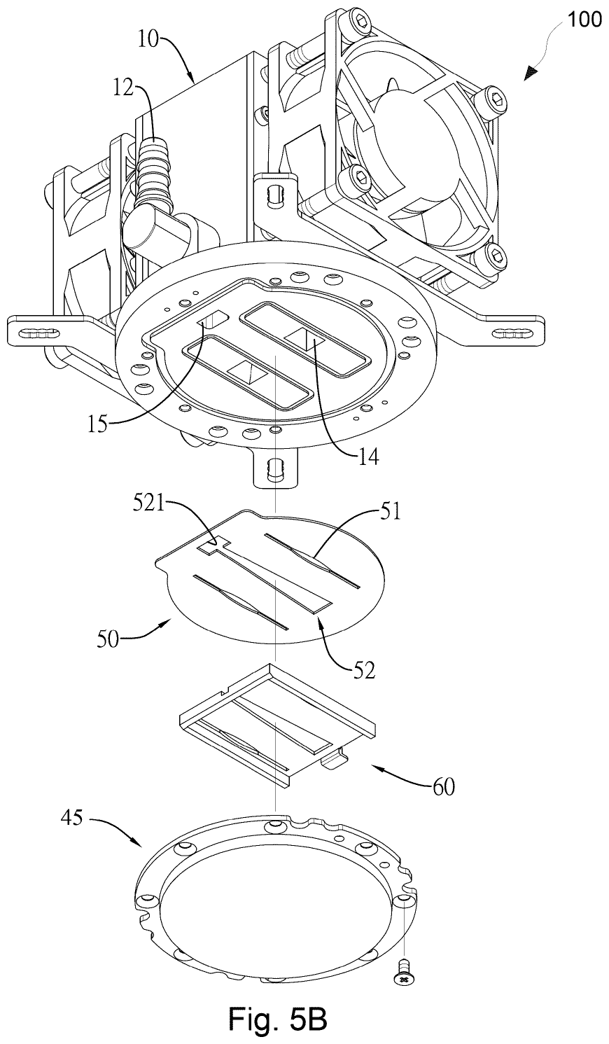

FIGS. 1A, 1B, 2, 3, 4, 5A, and 5B illustrate a cooling system assembly 100, in accordance with various embodiments of the present disclosure. The cooling system assembly 100 includes a housing 10 and two pump assemblies 20, 25. The housing 10 includes two pump cavities 13, an inlet 11, and an outlet 12. Each two pump cavities 13 is disposed parallel against each other and fluidly connected to the inlet 11 and to the outlet 12; thus, a footprint of the cooling system assembly 100 is minimized. Each two pump cavities 13 includes a pump cavity inlet 16, and a pump cavity outlet 14. Each two pump assemblies 20, 25 is respectively disposed in each two pump cavities 13. Each two pump assemblies 20, 25 includes an impeller casing 22 and a liquid driving assembly 30, 31. The impeller casing 22 includes a driving chamber 132, a driving chamber inlet 210, and a driving chamber outlet 290. The liquid driving assembly 30, 31 is disposed in the driving chamber 132. The liquid driving assembly 30, 31 includes a power source 30, and an impeller 31. Each impeller casing 22 defines an inlet chamber 131 separate from the driving chamber 132. Each power source 30 is configured to respectively drive each impeller 31 to rotate relative to each driving chamber 132. Each pump cavity inlet 16 is respectively disposed between each inlet chamber 131 and the inlet 11, and each pump cavity inlet 16 respectively connects the inlet 11 to each inlet chamber 131.

In some embodiments, each two pump assemblies 20, 25 is parallel connected, whereby flow rates of each two pump assemblies 20, 25 are combined to equal a total combined flow rate, improving heat-exchange efficiency of the cooling system assembly 100.

In some embodiments, the housing 10 further includes a housing partition 105. Each inlet chamber 131 is separated by the housing partition 105. The housing partition 105 includes a housing partition cut-out 1050 defining each pump cavity inlet 16 between each inlet chamber 131 and the inlet 11.

In some embodiments, the cooling system assembly 100 further includes a plurality of pillars 109 respectively coupled between each two pump cavities 13 and each two pump assemblies 20, 25. The plurality of pillars 109 is respectively disposed within each inlet chamber 131.

In some embodiments, the features of each two pump cavities 13 are the housing partition 105, the housing partition cut-out 105, and each pump cavity outlet 14, whereby the plurality of pillars 109 is respectively disposed within each inlet chamber 131. With each impeller casing 22 separating each inlet chamber 131 from each driving chamber 132, the features of each two pump cavities 13 are minimized, decreasing the amount of features of each two pump cavities 13 that may wear out or become damaged, and simplifying maintenance, repair or replacement of each two pump assemblies 20, 25.

In some embodiments, the power source 30 includes a stator 19 and a printed circuit board 17. In some embodiments, each two pump assemblies 20, 25 further includes a fan 23 disposed on each two pump assemblies 20, 25.

In some embodiments, the cooling system assembly 100 further includes a base plate 45 disposed on the housing 10 and perpendicular to each two pump cavities 13. The base plate 45 includes a plate cavity 41 and a thermal contact surface 40 on an opposite side of the plate cavity 41. The plate cavity 41 includes a heat exchange chamber 43 and a plurality of heat transfer surface features 42. The plurality of heat transfer surface features 42 is disposed in the heat exchange chamber 43. As an example, the plurality of heat transfer surface features 42 can be a microchannel first heat sink 73A. The thermal contact surface 40 is configured to be in thermal contact with a heat source (not shown). A heat exchange chamber outlet 15 of the housing 10 is disposed between the outlet 12 and the heat exchange chamber 43, and the heat exchange chamber outlet 15 connects the heat exchange chamber 43 to the outlet 12.

In some embodiments, the cooling system assembly 100 further includes a flow plate 50 and a fin flow plate 60. The fin flow plate 60 is disposed on the plurality of heat transfer surface features 42 and the flow plate 50 is disposed on the fin flow plate 60 and between the base plate 45 and the housing 10. The flow plate 50 includes two inlet slits 51. Each two inlet slits 51 is longitudinally disposed through the flow plate 50 and parallel towards each other. The fin flow plate 60 includes two fin inlet slits 61. Each two fin inlet slits 61 is longitudinally disposed through the fin flow plate 60 and parallel towards each other. Each two fin inlet slits 61, each two inlet slits 51, each pump cavity outlet 14, and each driving chamber outlet 290 are respectively disposed between the heat exchange chamber 43 and each driving chamber 132, and each driving chamber outlet 290, each pump cavity outlet 14, each two inlet slits 51, and each two fin inlet slits 61 respectively connect each driving chamber 132 to the heat exchange chamber 43. Each two inlet slits 51 and each two fin inlet slits 61 correspond in size and align with one another. Each two inlet slits 51 and each two fin inlet slits 61 can be an elliptical shape with flat pointed ends. In some embodiments, a material of the flow plate 50 includes a thermally conductive material such as copper, aluminum, or other thermally conductive metals. In some embodiments, a material of the fin flow plate 60 includes elastomer and thermoplastic materials such as rubber, silicone, or other elastomer and thermoplastic materials.

In some embodiments, the flow plate 50 further includes an outlet through hole 521. The outlet through hole 521 is disposed between the outlet 12 and the heat exchange chamber 43, and the outlet through hole 521 further connects the heat exchange chamber 43 to the outlet 12.

In some embodiments, the flow plate 50 further includes an outlet slit 52, and wherein the fin flow plate 60 further includes a fin outlet slit 62. The outlet slit 52 is longitudinally disposed centrally through the flow plate 50 between each two inlet slits 51. The outlet slit 52 includes a base end 522 and a neck end 523. The fin outlet slit 62 is longitudinally disposed centrally through the fin flow plate 60 between each two fin inlet slits 61. The fin outlet slit 62 includes a fin base end 622 and a fin neck end 623. The outlet through hole 521 is disposed connected to the neck end 523. The outlet slit 52 and the fin outlet slit 62 are respectively disposed between the outlet 12 and the heat exchange chamber 43, and the fin outlet slit 62 and outlet slit 52 further connect the heat exchange chamber 43 to the outlet 12.

In some embodiments, a base width of the base end 522 is equal to a fin base width of the fin base end 622 and a neck width of the neck end 523 is equal to a fin neck width of the fin neck end 623. The base width and the fin base width are greater than the neck width and the fin neck width. Each outlet slit 52 and fin outlet slit 62 correspond in size and align with one another. Each outlet slit 52 and fin outlet slit 62 can be trapezoidal in shape. In some embodiments, the fin flow plate 60 further includes a fin plate outlet cut-out 629 disposed on an end of the fin neck end 623.

The fin outlet slit 62 and the outlet slit 52 provide an additional flow path for cooling fluid to exit the heat exchange chamber 43. The trapezoidal shapes increase the flow rate of cooling fluid at the fin neck end 623 and the neck end 523. Additionally, the fin plate outlet cut-out 629 increases the volume of cooling fluid flow to the outlet through hole 521 and the heat exchange chamber outlet 15. The increased flow rate and volume of the trapezoidal shape of the fin outlet slit 62 and the outlet slit 52, and the fin plate outlet cut-out 629, respectively, decrease the flow resistance at the outlet through hole 521 and the heat exchange chamber outlet 15. Thus, turbulence at the outlet through hole 521 and the heat exchange chamber outlet 15 is decreased and in turn, heat-exchange efficiency is enhanced.

In some embodiments, each liquid driving assembly 30, 31 drives cooling fluid to flow from the inlet 11 to each inlet chamber 131, to each driving chamber 132, and then to the heat exchange chamber 43. Flow rates of each two pump assemblies 20, 25 are combined to equal a total combined flow rate. As the cooling fluid circulates through the heat exchange chamber 43, thermal energy is exchanged between the base plate 45 and cooling fluid and, as a result, the temperature of the base plate 45 is reduced, and in turn, the temperature of the heat source is reduced, and the temperature of the cooling fluid increases. Heat is transferred from the heat source to the base plate 45, to the cooling fluid, and then to a heat dissipation device and the ambient environment.

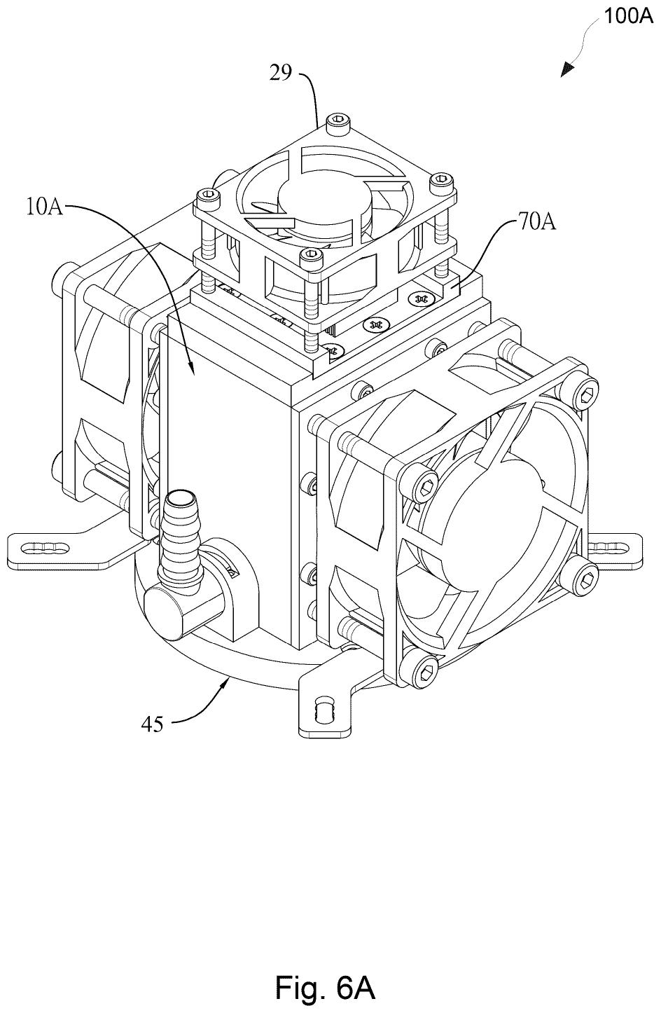

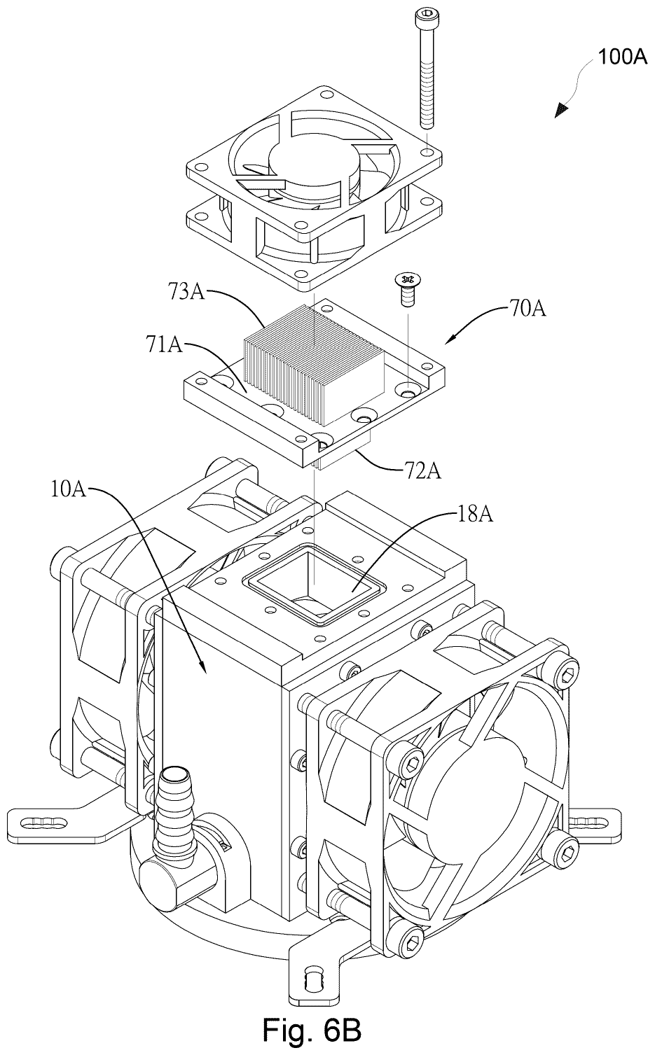

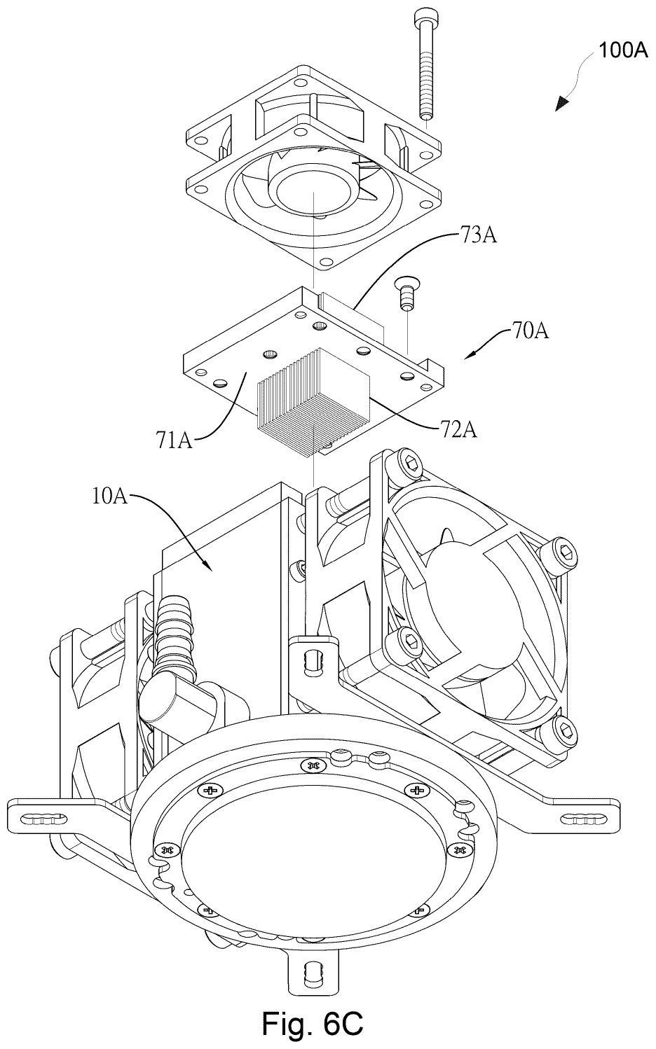

In some embodiments, the cooling system assembly 100A, 100B further includes at least one heat exchanger 70A, 70B, and the housing 10 further includes a heat exchanger opening 18A (as shown in FIGS. 6B, 7, and 8B). Each inlet chamber 131 is disposed between the inlet 11 and the heat exchanger opening 18A, and each inlet chamber 131 respectively connects the inlet 11 to the heat exchanger opening 18A. The at least one heat exchanger 70A, 70B is disposed in the heat exchanger opening 18A. In some embodiments, the at least one heat exchanger 70A, 70B further includes a heat exchanger fan 29 disposed on the at least one heat exchanger 70A, 70B.

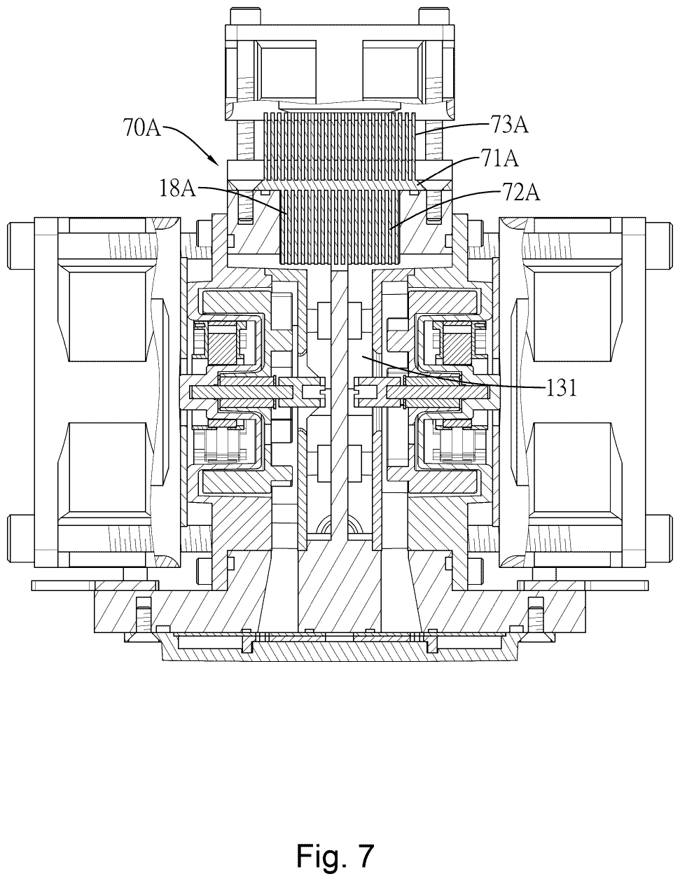

FIGS. 6A, 6B, 6C and 7 illustrate an alternative cooling system assembly 100A, in accordance with various embodiments of the present disclosure. The at least one heat exchanger 70A, 70B of the alternative cooling system assembly 100A includes a first heat exchanger 70A. The alternative cooling system assembly 100A may be similar in some respects to the cooling system assembly 100 of FIGS. 1A to 5B, and therefore may be best understood with reference thereto where like numerals designate like components not described again in detail. The difference between the alternative cooling system assembly 100A and the cooling system assembly 100 is that the alternative cooling system assembly 100A further includes the first heat exchanger 70A, and the housing 10A further includes the heat exchanger opening 18A. The first heat exchanger 70A includes a first cover plate 71A, a plurality of first heat transfer surface features 72A, and a first heat sink 73A. The plurality of first heat transfer surface features 72A is disposed on one side of the first cover plate 71A and the first heat sink 73A is disposed on an opposite side of the first cover plate 71A. The plurality of first heat transfer surface features 72A is disposed in the heat exchanger opening 18A. As cooling fluid circulates through each inlet chamber 131, thermal energy is exchanged between the cooling fluid and the plurality of first heat transfer surface features 72A, the first heat transfer surface features 72A and the first cover plate 71A, and the first cover plate 71A and the first heat sink 73A. As a result, the temperature of the cooling fluid in the inlet chamber 131 is reduced, and the temperature of the plurality of first heat transfer surface features 72A, the first cover plate 71A, and the first heat sink 73A increases. Heat is transferred from the cooling fluid in the inlet chamber 131 to the plurality of first heat transfer surface features 72A, the first cover plate 71A, and the first heat sink 73A, and then the ambient environment. Thus, heat-exchange efficiency is furthermore enhanced.

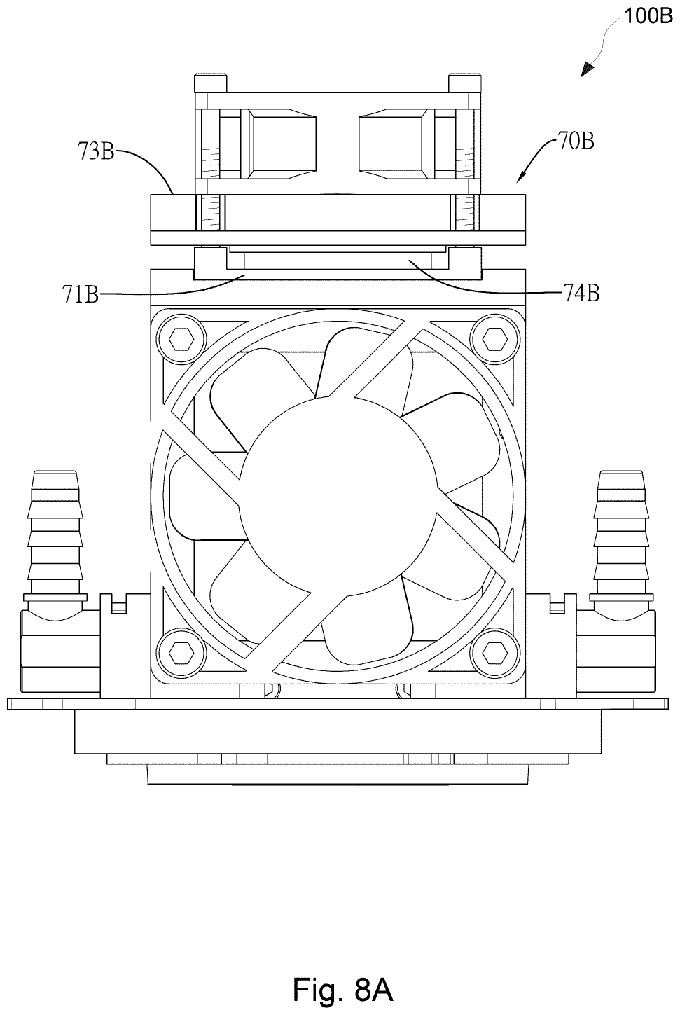

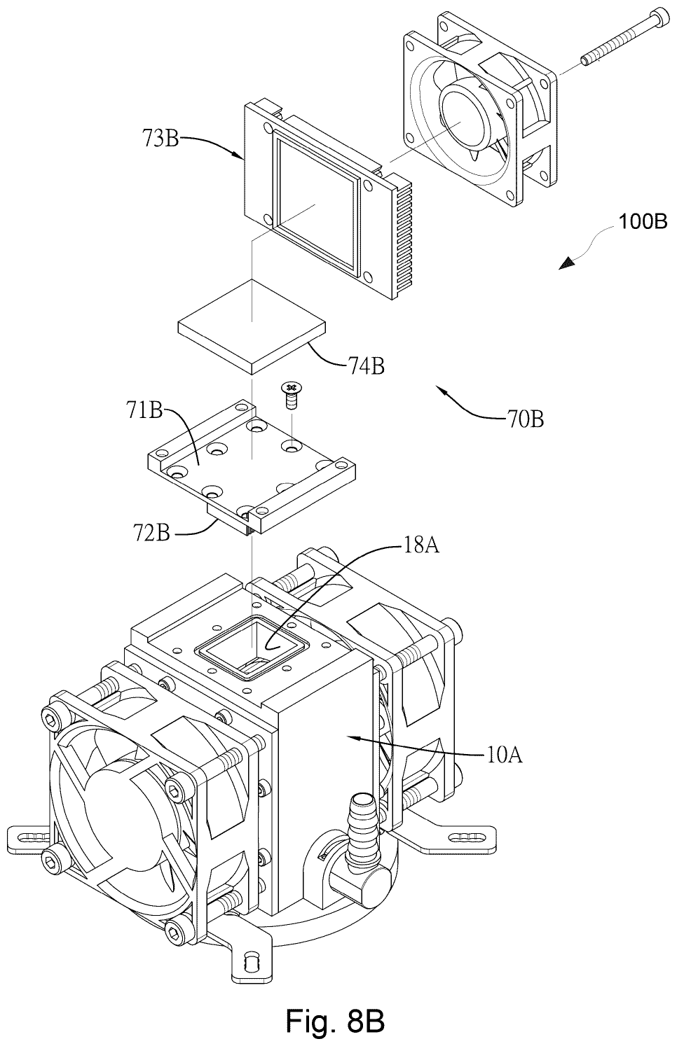

FIGS. 8A and 8B illustrate another alternative cooling system assembly 100B, in accordance with various embodiments of the present disclosure. The at least one heat exchanger 70A, 70B of the another alternative cooling system assembly 100B includes a second heat exchanger 70B. The another alternative cooling system assembly 100B may be similar in some respects to the cooling system assembly 100 of FIGS. 1A to 5B, and therefore may be best understood with reference thereto where like numerals designate like components not described again in detail. The difference between the another alternative cooling system assembly 100B and the cooling system assembly 100 is that the another alternative cooling system assembly 100B further includes the second heat exchanger 70B, and the housing 10A further includes the heat exchanger opening 18A. The second heat exchanger 70B includes a second cover plate 71B, a plurality of second heat transfer surface features 72B, a thermoelectric module 74B, and a second heat sink 73B. The plurality of second heat transfer surface features 72B is disposed on one side of the second cover plate 71B and the thermoelectric module 74B disposed on an opposite side of the second cover plate 71B. The second heat sink 73B is disposed on the thermoelectric module 74B and the plurality of second heat transfer surface features 72B is disposed in the heat exchanger opening 18A. As cooling fluid circulates through each inlet chamber 131, thermal energy is exchanged between the cooling fluid and the plurality of second heat transfer surface features 72B, the second heat transfer surface features 72B and the second cover plate 71B, the second cover plate 71B and the thermoelectric module 74B, and the thermoelectric module 74B and the second heat sink 73B. As a result, the temperature of the cooling fluid in the inlet chamber 131 is reduced, and the temperature of the plurality of first heat transfer surface features 72B, the second cover plate 71B, the thermoelectric module 74B, and the second heat sink 73B increases. Heat is transferred from the cooling fluid in the inlet chamber 131 to the plurality of second heat transfer surface features 72B, the second cover plate 71B, the thermoelectric module 74B, and the second heat sink 73B, and then the ambient environment. Thus, heat-exchange efficiency is even furthermore enhanced.

Thermal conductivity of the cooling system assemblies 100, 100A, 100B of the embodiments of the present disclosure is increased. To begin, the two pump assemblies 20, 25 are parallel connected, combining their flow rates. Also, the two pump assemblies 20, 25 are disposed parallel against each other in two pump cavities 13 of one housing 10, 10A,. Accordingly, flow rate is increased while minimizing footprint (or amount of space the cooling system assemblies 100, 100A, 100B occupy), improving heat-exchange efficiency. Moreover, in addition to the heat exchange chamber outlet 15 and the outlet through hole 521 connecting the heat exchange chamber 43 to the outlet 12, the fin outlet slit 62 and the outlet slit 52, also connect the heat exchange chamber 43 to the outlet 12. The fin outlet slit 62 and the outlet slit 52, respectively longitudinally disposed centrally on the fin flow plate 60 and the flow plate 50, provide an additional flow path for cooling fluid to exit the heat exchange chamber 43. The trapezoidal shape of the fin flow plate 60 and the flow plate 50 increases the flow rate of cooling fluid at the fin neck end 623 and the neck end 523 of the fin outlet slit 62 and the outlet slit 52, respectively. Additionally, the fin plate outlet cut-out 629 disposed on the end of the fin neck end 623 increases the volume of cooling fluid flow to the heat exchange chamber outlet 15 and the outlet through hole 521. The increased flow rate and volume of the trapezoidal shape of the fin outlet slit 62 and the outlet slit 52, and the fin plate outlet cut-out 629, respectively, decrease the flow resistance at the heat exchange chamber outlet 15 and the outlet through hole 521, thus, decreasing turbulence at the heat exchange chamber outlet 15 and the outlet through hole 521 and in turn enhancing heat-exchange efficiency. Furthermore, the features of each two pump cavities 13 of the housing 10 are decreased with the addition of each impeller casing 22. Each inlet chamber 131 defined by each impeller casing 22 is separated by the housing partition 105. The housing partition cut-out 1050 defines each pump cavity inlet 16 between each inlet chamber 131 and the inlet 11. Each impeller casing 22 also separates each driving chamber 132 from the impeller casing 22. The features of each two pump cavities 13 are the housing partition 105, the housing partition cut-out 1050, and each pump cavity outlet 14, whereby the plurality of pillars 109 is respectively disposed within each inlet chamber 131. Thus, the two pump assemblies 20, 25 increase flow rate while minimizing footprint, and the trapezoidal shape of the fin outlet slit 62 and the outlet slit 52, and the fin plate outlet cut-out 629, respectively, increases flow rate and volume and decreases the flow resistance and turbulence at the heat exchange chamber outlet 15 and the outlet through hole 521 to in turn enhance heat-exchange efficiency, increasing thermal conductivity of the cooling system assemblies 100, 100A, 100B of the embodiments of the present disclosure. Additionally, features of each two pump cavities 13 of the housing 10 are decreased with the addition of each impeller casing 22, decreasing the amount of features of each two pump cavities 13 that may wear out or become damaged, and simplifying maintenance, repair or replacement of each two pump assemblies 20, 25.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A cooling system assembly, comprising:
a housing including two pump cavities, an inlet, and an outlet, each two pump cavities is disposed parallel against each other and fluidly connected to the inlet and to the outlet;
wherein each two pump cavities, comprises:
a pump cavity inlet; and
a pump cavity outlet; and
two pump assemblies, each two pump assemblies respectively disposed in each two pump cavities;
wherein each two pump assemblies, comprises:
an impeller casing including a driving chamber, a driving chamber inlet, and a driving chamber outlet; and
a liquid driving assembly disposed in the driving chamber;
wherein the liquid driving assembly, comprises:
a power source; and
an impeller;
wherein each impeller casing defines an inlet chamber separate from the driving chamber;
wherein each power source is configured to respectively drive each impeller to rotate relative to each driving chamber; and
wherein each pump cavity inlet is respectively disposed between each inlet chamber and the inlet, and each pump cavity inlet respectively connects the inlet to each inlet chamber.

2. The cooling system assembly of claim 1, further comprising a plurality of pillars respectively coupled between each two pump cavities and each two pump assemblies, the plurality of pillars respectively disposed within each inlet chamber.

3. The cooling system assembly of claim 1, further comprising a base plate disposed on the housing and perpendicular to each two pump cavities, the base plate including a plate cavity and a thermal contact surface on an opposite side of the plate cavity, the plate cavity comprising a heat exchange chamber and a plurality of heat transfer surface features, the plurality of heat transfer surface features disposed in the heat exchange chamber, the thermal contact surface configured to be in thermal contact with a heat source, and a heat exchange chamber outlet of the housing is disposed between the outlet and the heat exchange chamber, and the heat exchange chamber outlet connects the heat exchange chamber to the outlet.

4. The cooling system assembly of claim 3, further comprising a flow plate and a fin flow plate, the fin flow plate disposed on the plurality of heat transfer surface features, the flow plate disposed on the fin flow plate and between the base plate and the housing, the flow plate including two inlet slits, each two inlet slits longitudinally disposed through the flow plate and parallel towards each other, the fin flow plate including two fin inlet slits, each two fin inlet slits longitudinally disposed through the fin flow plate and parallel towards each other, and each two fin inlet slits, each two inlet slits, each pump cavity outlet, and each driving chamber outlet are respectively disposed between the heat exchange chamber and each driving chamber, and each driving chamber outlet, each pump cavity outlet, each two inlet slits, and each two fin inlet slits respectively connect each driving chamber to the heat exchange chamber.

5. The cooling system assembly of claim 4, wherein the flow plate further comprises an outlet through hole, the outlet through hole is disposed between the outlet and the heat exchange chamber, and the outlet through hole further connects the heat exchange chamber to the outlet.

6. The cooling system assembly of claim 5, wherein the flow plate further comprises an outlet slit longitudinally disposed centrally through the flow plate between each two inlet slits, the outlet slit including a base end and a neck end, and wherein the fin flow plate further comprises a fin outlet slit longitudinally disposed centrally through the fin flow plate between each two fin inlet slits, the fin outlet slit including a fin base end and a fin neck end, the outlet through hole disposed connected to the neck end, and the outlet slit and the fin outlet slit are respectively disposed between the outlet and the heat exchange chamber, and the fin outlet slit and outlet slit further connect the heat exchange chamber to the outlet.

7. The cooling system assembly of claim 6, wherein a base width of the base end is equal to a fin base width of the fin base end and a neck width of the neck end is equal to a fin neck width of the fin neck end, the base width and the fin base width are greater than the neck width and the fin neck width.

8. The cooling system assembly of claim 6, wherein the fin flow plate further comprises a fin plate outlet cut-out disposed on an end of the fin neck end.

9. The cooling system assembly of claim 1, further comprising at least one heat exchanger, and wherein the housing further comprises a heat exchanger opening, and each inlet chamber is disposed between the inlet and the heat exchanger opening, each inlet chamber respectively connects the inlet to the heat exchanger opening, and the at least one heat exchanger is disposed in the heat exchanger opening.

10. The cooling system assembly of claim 9, wherein the at least one heat exchanger comprises a first heat exchanger including a first cover plate, a plurality of first heat transfer surface features, and a heat sink, the plurality of first heat transfer surface features disposed on one side of the first cover plate, the heat sink is disposed on an opposite side of the first cover plate, the plurality of first heat transfer surface features disposed in the heat exchanger opening.

11. The cooling system assembly of claim 9, wherein the at least one heat exchanger comprises a second heat exchanger including a second cover plate, a plurality of second heat transfer surface features, a thermoelectric module, and a second heat sink, the plurality of second heat transfer surface features disposed on one side of the second cover plate, the thermoelectric module disposed on an opposite side of the second cover plate, the second heat sink disposed on the thermoelectric module, the plurality of second heat transfer surface features disposed in the heat exchanger opening.

12. The cooling system assembly of claim 9, wherein the at least one heat exchanger further comprises a heat exchanger fan disposed on the at least one heat exchanger.

13. The cooling system assembly of claim 1, wherein the power source comprises a stator and a printed circuit board.

14. The cooling system assembly of claim 1, wherein each two pump assemblies further comprises a fan disposed on each two pump assemblies.
